(19) United States
(12) Patent Application Publication
(10) Pub. No.: US 2010/0317169 A1
(43) Pub. Date: Dec. 16, 2010

(54) METHODS OF FABRICATING NON-VOLATILE MEMORY DEVICES USING INCLINED ION IMPLANTATION

(75) Inventors: Suk-kang Sung, Seongnam-si (KR); Keon-soo Kim, Hwaseong-si (KR); Min-chul Kim, Hwaseong-si (KR); Se-jun Park, Suwon-si (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/708,030

(22) Filed: Feb. 18, 2010

(30) Foreign Application Priority Data
Jun. 12, 2009 (KR) 10-2009-0052356

(51) Int. Cl. H01L 21/336

(52) U.S. Cl. 438/287; 438/302; 257/E21.433; 257/E21.423

(57) ABSTRACT

Provided is a method of manufacturing a non-volatile memory device by performing ion implantation at an angle such that active regions of memory cell transistors in a cell region and peripheral transistors in a peripheral region each have different doping concentrations. The method includes forming a plurality of memory cell transistor gates on a cell region of a substrate surface and a plurality of peripheral transistor gates on a peripheral region of the substrate surface, where a distance between adjacent ones of the peripheral transistor gates is greater than a distance between adjacent ones of the memory cell transistor gates, and performing an ion implantation process at an implantation angle that is selected based on a height of the memory cell transistor gates and the distance between the adjacent ones thereof to implant ions into portions of the peripheral region between the peripheral transistor gates without implanting the ions into portions of the cell region between the memory cell transistor gates.

### CROSS-REFERENCE TO RELATED APPLICATIONS

This application claims priority from Korean Patent Application No. 10-2009-0052356, filed on Jun. 12, 2009, in the Korean Intellectual Property Office, the disclosure of which is incorporated by reference herein in its entirety.

### BACKGROUND

The inventive concept relates to methods of manufacturing non-volatile memory devices, and more particularly, to methods of fabricating non-volatile memory devices using ion implantation.

Due to market demands, non-volatile memory devices may be required to have smaller sizes and a higher-capacities. Accordingly, in order to simplify manufacturing processes, memory cell transistors in a cell region of the device and peripheral transistors in a peripheral region of the device may be simultaneously formed.

### SUMMARY

According to some embodiments of the inventive concept, a method of manufacturing a non-volatile memory device includes preparing a semiconductor layer including a cell region and a peripheral region, forming a plurality of cell transistors in the cell region and a plurality of peripheral transistors in the peripheral region, implanting first ions at a first angle θ1 into cell source/drain regions of the cell transistors and peripheral source/drain regions of the peripheral transistors, and implanting second ions different from the first ions at a second angle θ2 into the peripheral source/drain regions and not into the cell source/drain regions.

In some embodiments, the first angle θ1 may be in a range of 0≦θ1≦θ1(max), wherein, θ1(max)=tan⁻¹(W1/H1), H1 is a first height of each of the cell transistors, and W1 is the interval between the cell transistors.

In some embodiments, the second angle θ2 may be in a range of θ1(max)<θ2≦θ2(max), wherein θ2(max)=tan⁻¹(W2/H2), H2 is a second height of each of the peripheral transistors, and W2 is the interval between the peripheral transistors.

In some embodiments, at least one of the implanting of the first ions and the second ions may be performed in a double-mode, at a same angle from at least two different directions.

In some embodiments, the first ions and the second ions may include Group III elements or Group V elements, respectively. Also, the first ions and the second ions may be different from each other. In addition, the molecular weights of the first ions may be greater than those of the second ions. Moreover, the first ions may include arsenic (As) and the second ions may include phosphorus (P).

In some embodiments, the cell transistors each may include a tunneling insulating layer, a charge storage layer, a blocking insulating layer, and a cell gate electrode that are stacked sequentially on the semiconductor layer.

According to further embodiments of the inventive concept, there is provided a method of manufacturing a non-volatile memory device, the method including: preparing a semiconductor layer including a cell region and a peripheral region; forming a plurality of cell transistors each including a charge storage layer in the cell region and a plurality of peripheral transistors in the peripheral region; and implanting second ions at a second angle θ2 into peripheral source/drain regions of the peripheral transistors and not into cell source/drain regions of the cell transistors, wherein the second angle θ2 is in a range of θ1(max)<θ2≦θ2(max), wherein θ1(max)=tan⁻¹(W1/H1), θ2(max)=tan⁻¹(W2/H2), H2 is the second height of each of the peripheral transistors, and W2 is the interval between the peripheral transistors, H1 is the first height of each of the cell transistors, and W1 is the interval between the cell transistors.

According to still further embodiments of the inventive concept, a method of manufacturing a non-volatile memory device includes forming a plurality of memory cell transistor gates on a cell region of a substrate surface and a plurality of peripheral transistor gates on a peripheral region of the substrate surface. A distance between adjacent ones of the peripheral transistor gates is greater than a distance between adjacent ones of the memory cell transistor gates. An ion implantation process is performed at an implantation angle that is selected based on a height of the memory cell transistor gates and the distance between the adjacent ones thereof to implant ions into portions of the peripheral region between the peripheral transistor gates without implanting the ions into portions of the cell region between the memory cell transistor gates.

In some embodiments, the height of the memory cell transistor gates may be sufficient to block implantation of the ions into the portions of the cell region therebetween in response to performing the ion implantation process at the implantation angle.

In some embodiments, the implantation angle may be measured relative to a normal to the substrate surface, and the implantation angle may be greater than an inverse tangent of the distance between the adjacent ones of the memory cell transistor gates divided by the height of the memory cell transistor gates.

In some embodiments, the implantation angle may not be greater than an inverse tangent of the distance between adjacent ones of the peripheral transistor gates divided by a height of the peripheral transistor gates.

In some embodiments, the implantation angle may be a second implantation angle, and the ion implantation process may be a second ion implantation process to implant second ions at the second implantation angle. The method may further include performing a first ion implantation process at a first implantation angle different from the second implantation angle to implant first ions into the portions of the cell region between the memory cell transistor gates and into the portions of the peripheral region between the peripheral transistor gates.

In some embodiments, the first implantation angle may be measured relative to the normal to the substrate surface, and the second implantation angle may be greater than the first implantation angle.

In some embodiments, the first implantation angle may not be greater than the inverse tangent of the distance between the adjacent ones of the memory cell transistor gates divided by the height of the memory cell transistor gates.

In some embodiments, the first ions may be ions of a different material than the second ions. For example, the first ions may have a greater molecular weight than the second ions.

In some embodiments, performing the ion implantation process may include performing the ion implantation process at the implantation angle from at least two different directions to provide double-mode ion implantation.

### BRIEF DESCRIPTION OF THE DRAWINGS

FIG. 1 is a block diagram of a non-volatile memory device according to some embodiments of the inventive concept;

FIG. 2 illustrates the layout of a portion of a memory cell array of the non-volatile memory device of FIG. 1, according to some embodiments of the inventive concept;

FIGS. 3A and 3B are cross-sectional views taken along lines I-I′ and II-II′ of FIG. 2, respectively;

FIG. 4 is a flowchart illustrating a method of manufacturing a non-volatile memory device, according to some embodiments of the inventive concept;

FIGS. 5A through 5D are cross-sectional views sequentially illustrating methods of manufacturing a non-volatile memory device, according to some embodiments of the inventive concept;

FIGS. 6A and 6B are cross-sectional views illustrating a range of a first angle at which first ions are implanted and a range of a second angle at which second ions are implanted, respectively, according to some embodiments of the inventive concept;

FIG. 7 is a diagram illustrating a memory card according to some embodiments of the inventive concept; and

FIG. 8 is a diagram illustrating a system according to some embodiments of the inventive concept.

### DETAILED DESCRIPTION OF THE EMBODIMENTS

The present invention will now be described more fully hereinafter with reference to the accompanying drawings, in which embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like numbers refer to like elements throughout.

It will be understood that when an element or layer is referred to as being “on”, “connected to” or “coupled to” another element or layer, it can be directly on, connected or coupled to the other element, or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “bottom”, “lower”, “above”, “top”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. Also, as used herein, “lateral” refers to a direction that is substantially orthogonal to a vertical direction.

The terminology used herein is for the purpose of describing particular embodiments only, and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. Accordingly, these terms can include equivalent terms that are created after such time. It will be further understood that terms, such as those defined in commonly used dictionaries, should be interpreted as having a meaning that is consistent with their meaning in the present specification and in the context of the relevant art, and will not be interpreted in an idealized or overly formal sense unless expressly so defined herein.

Reference will now be made in detail to exemplary embodiments, examples of which are illustrated in the accompanying drawings. However, exemplary embodiments are not limited to the embodiments illustrated hereinafter, and the embodiments herein are rather introduced to provide easy and complete understanding of the scope and spirit of exemplary embodiments. In the drawings, the thicknesses of layers and regions are exaggerated for clarity.

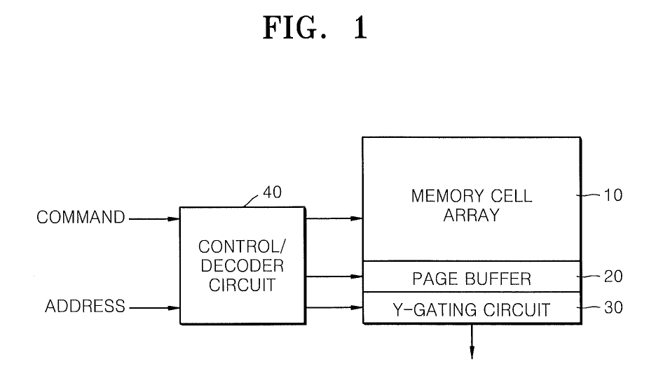

FIG. 1 is a block diagram of a non-volatile memory device according to some embodiments of the inventive concept.

Referring to FIG. 1, the non-volatile memory device may include a memory cell array 10, a page buffer 20, a Y-gating circuit 30, and a control/decoder circuit 40.

The memory cell array 10 may include a plurality of memory blocks, and each of the plurality of memory blocks may include a plurality of non-volatile memory cells. The non-volatile memory cells may be flash memory cells, NAND flash memory cells, or NOR flash memory cells. The page buffer 20 may temporarily store data to be written in the memory cell array 10, or data to be read from the memory cell array 10. The Y-gating circuitry 30 may transmit data stored in the page buffer 20. The control/decoder circuitry 40 may receive a command and an address from an external device, output a control signal to write data in the memory cell array 10 or to read data from the memory cell array 10, and decode the address. The control/decoder circuitry 40 may output a control signal for input and output of data to the page buffer 20 and provide address information to the Y-gating circuitry 30.

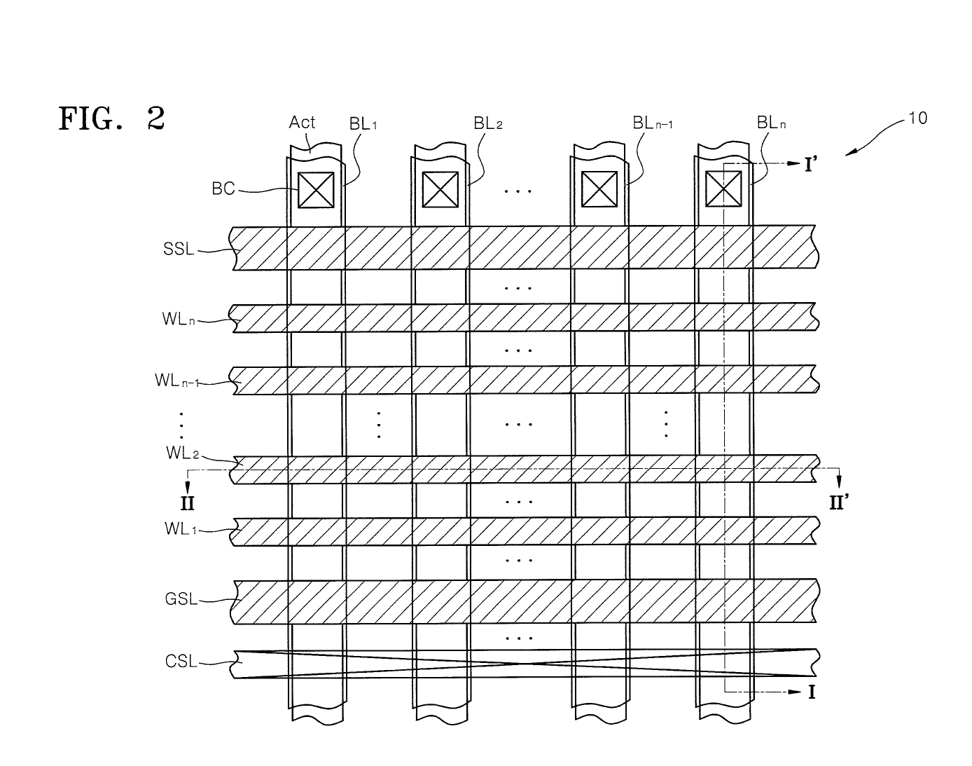

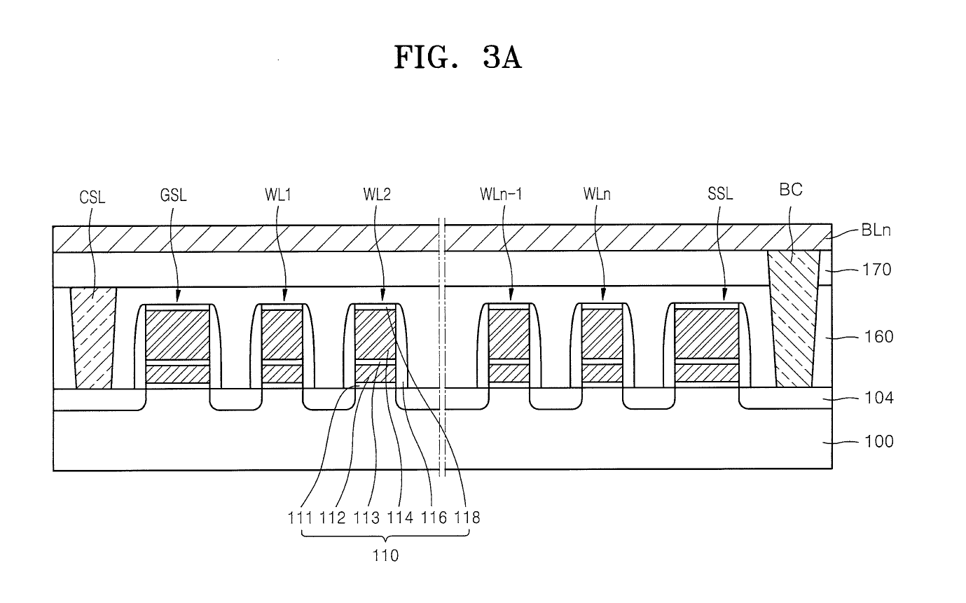

FIG. 2 illustrates the layout of a portion of the memory cell array 10 of the non-volatile memory device of FIG. 1, according to some embodiments of the inventive concept. FIGS. 3A and 3B are cross-sectional views taken along lines I-I′ and II-IP of FIG. 2, respectively.

Referring to FIGS. 2, 3A, and 3B, the memory cell array 10 may include a plurality of active regions Act that are defined by device isolation regions 102 formed on a semiconductor layer 100. The semiconductor layer 100 may include a substrate comprising semiconductor materials such as silicon and/or silicon-germanium, an epitaxial layer, a silicon-on-insulator (SOI) layer, and/or a semiconductor-on-insulator (SEM) layer. The active regions Act may define parallel lines.

A string selection line SSL and a ground selection line GSL may run across and over the active regions Act. A plurality of word lines WL1, WL2, . . . , WLn-1, and WLn may run across and over the active regions Act between the string selection line SSL and the ground selection line GSL. The string selection line SSL, the ground selection line GSL, and the word lines WL1, WL2, . . . , WLn-1, and WLn may be parallel to one another. Impurity regions 104 may be formed in the active regions Act adjacent to both sides of each of the word lines WL1, WL2, . . . , WLn-1, and WLn, the string selection line SSL, and the ground selection line GSL. As a result, a string selection transistor, cell transistors, and a ground selection transistor that are connected in series are formed. The string selection transistor, the ground selection transistor, and the cell transistors interposed therebetween may constitute a unit memory block. The impurity region 104 disposed adjacent to the string selection line SSL and opposite to the ground selection line GSL may be defined as a drain region of the string selection transistor. Also, the impurity region 104 disposed adjacent to the ground selection line GSL and opposite to the string selection line SSL may be defined as a source region of the ground selection transistor.

Each of the word lines WL1, WL2, . . . , WLn-1, and WLn may include a tunneling insulating layer 111, a charge storage layer 112, a blocking insulating layer 113, and a cell gate electrode 114 that are stacked sequentially on the semiconductor layer 100 to define a cell transistor 110. Although not illustrated, each of the word lines WL1, WL2, . . . , WLn-1, and WLn may further include a cell barrier conductive layer and a word line conductive layer that are stacked sequentially on the cell gate electrode 114.

Each of the tunneling insulating layer 111 and the charge storage layer 112 may be separated into portions with respect to the cell transistors disposed adjacently in the direction of the word lines WL1, WL2, . . . , WLn-1, and WLn. Top surfaces of the device isolation regions 102 may be at substantially the same level as a top surface of the charge storage layer 112. The tunneling insulating layer 111 may be a silicon oxide layer. The charge storage layer 112 may be a charge trapping layer or a floating gate conductive layer. The blocking insulating layer 113 may be shared among the cell transistors disposed adjacently in the direction of the word lines WL1, WL2, . . . , WLn-1, and WLn. A cell spacer 116 may be disposed on side surfaces of the tunneling insulating layer 111, the charge storage layer 112, the blocking insulating layer 113, and the cell gate electrode 114. The cell spacer 116 may be formed as a multi layer.

A string selection line SSL and a ground selection line GSL may have the same or similar stacked structures as word lines WL1, WL2, . . . , WLn-1, and WLn as described above. The widths of the string selection line SSL and the ground selection line GSL may be greater than those of the word lines WL1, WL2, . . . , WLn-1, and WLn in some embodiments; however, the present inventive concept is not limited thereto.

A first interlayer insulating layer 160 is provided on the word lines WL1, WL2, . . . , WLn-1, and WLn, the string selection line SSL and the ground selection line GSL. A common source line CSL is disposed through the first interlayer insulating layer 160 and connected to the source region of the ground selection line GSL. The common source line CSL may be disposed parallel to the ground selection line GSL. A second interlayer insulating layer 170 may be provided on the first interlayer insulating layer 160. A bit line plug BC may be disposed through the second interlayer insulating layer 170 and the first interlayer insulating layer 160 and connected to the drain region of the string selection line SSL. Bit lines BL1, BL2, . . . , BLn-1, and BLn may be disposed on the second interlayer insulating layer 170 and connected to the bit line plug BC. Also, the bit lines BL1, BL2, . . . , BLn-1, and BLn run across and over the word lines WL1, WL2, . . . , WLn-1, and WLn. The bit lines BL1, BL2, . . . , BLn-1, and BLn may be disposed parallel to the active regions Act.

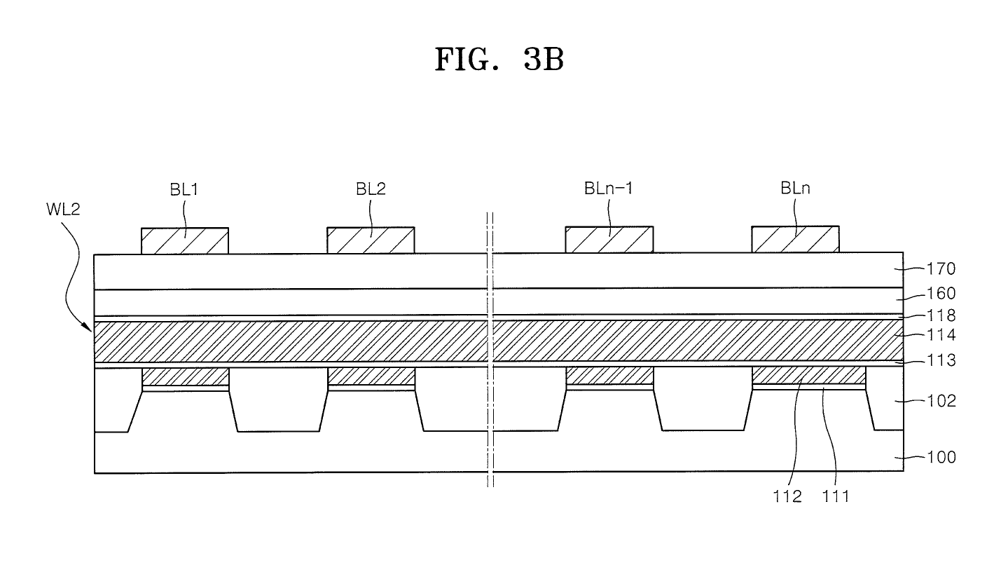

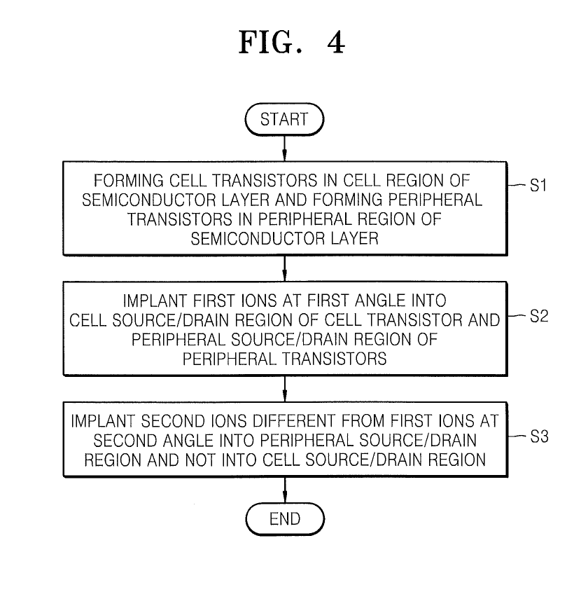

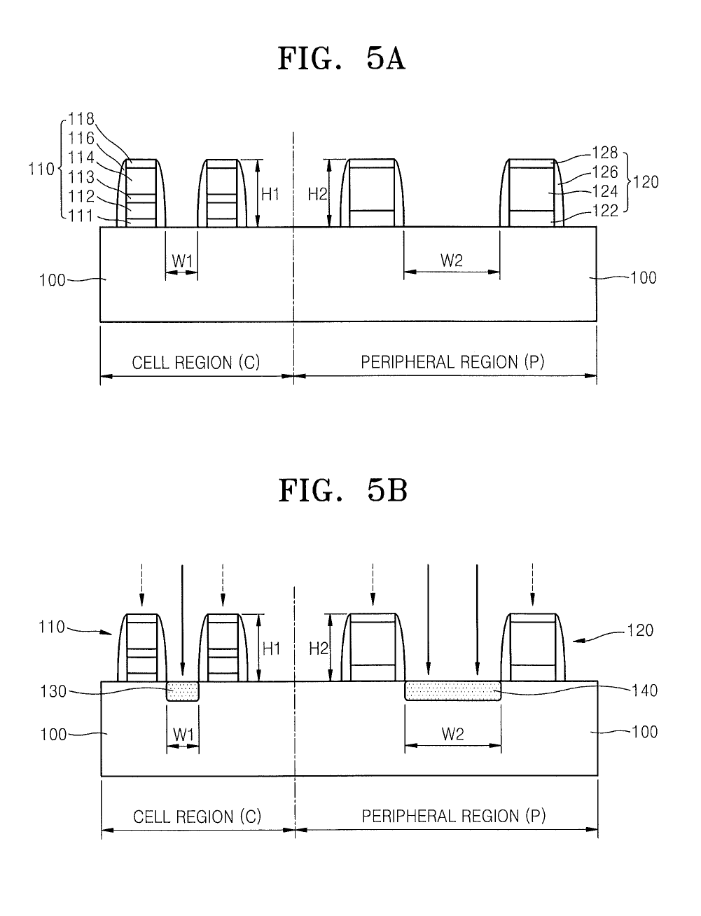

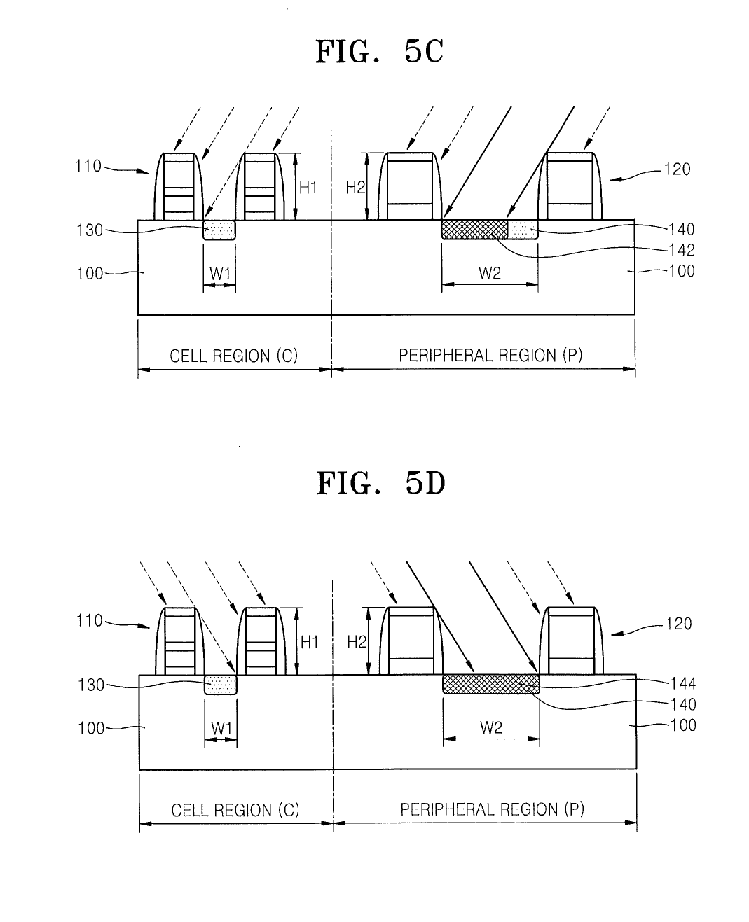

FIG. 4 is a flowchart illustrating a method of manufacturing non-volatile memory devices, according to some embodiments of the inventive concept, and FIGS. 5A through 5D are cross-sectional views sequentially illustrating a method of manufacturing a non-volatile memory devices, according to some embodiments of the inventive concept.

Referring to FIGS. 4 and 5A, the semiconductor layer 100 in which a cell region C and a peripheral region P are defined is prepared. Then, a plurality of cell transistors 110 are formed in the cell region C and a plurality of peripheral transistors 120 are formed in the peripheral region P, in operation Si.

The semiconductor layer 100 may include a substrate including semiconductor materials such as silicon and/or silicon-germanium, an epitaxial layer, a silicon-on-insulator (SOI) layer, and/or a semiconductor-on-insulator (SEOI) layer.

The cell transistors 110 may each include the tunneling insulating layer 111, the charge storage layer 112, the blocking insulating layer 113, the cell gate electrode 114, and the cell spacer 116. Optionally, a cell capping layer 118 may be further formed on the cell gate electrode 114.

The tunneling insulating layer 111 may be formed using thermal oxidation, chemical vapor deposition (CVD), low pressure CVD (LPCVD), plasma enhanced CVD (PECVD), atomic layer deposition (ALD), and/or sputtering. The method of forming the tunneling insulating layer 111 above may be applied to forming of the charge storage layer 112, the blocking insulating layer 113, the cell gate electrode 114, the cell spacer 116, and the cell capping layer 118 and details of the method are omitted for convenience of description. The tunneling insulating layer 111 may be a single layer or a multi-layer including at least one of silicon oxide (SiO₂), silicon oxynitride (SiON), silicon nitride (SiN), aluminum oxide (Al₂O₃), aluminum nitride (AlN), hafnium oxide (HfO₂), hafnium silicon oxide (HfSiO), hafnium silicon oxynitride (HfSiON), hafnium oxynitride (HfON), hafnium aluminum oxide (HfAlO), zirconium oxide (ZrO₂), tantalum oxide (Ta₂O₃), hafnium tantalum oxide (HfTaₓO_{y}), lanthanum oxide (LaO), lanthanum aluminum oxide (LaAlO), lanthanum hafnium oxide (LaHfO), and hafnium aluminum oxide(HfAlO).

The charge storage layer 112 may be a floating gate layer or a charge trap layer. The charge storage layer 112 may be a single layer or a multi-layer including at least one of polysilicon, silicon oxide (SiO₂), silicon oxynitride (SiON), silicon nitride (SiN), aluminum oxide (Al₂O₃), aluminum nitride (AlN), hafnium oxide (HfO₂), hafnium silicon oxide (HfSiO), hafnium silicon oxynitride (HfSiON), hafnium oxynitride (HfON), hafnium aluminum oxide (HfAlO), zirconium oxide (ZrO₂), tantalum oxide (Ta₂O₃), hafnium tantalum oxide (HfTaₓO_{y}), lanthanum oxide (LaO), lanthanum aluminum oxide (LaAlO), lanthanum hafnium oxide(LaHfO), and hafnium aluminum oxide(HfAlO).

The blocking insulating layer 113 may be a single layer or a multi-layer including at least one of silicon oxide (SiO₂), silicon oxynitride (SiON), silicon nitride (SiN), aluminum oxide (Al₂O₃), aluminum nitride (AlN), hafnium oxide (HfO₂), hafnium silicon oxide (HfSiO), hafnium silicon oxynitride (HfSiON), hafnium oxynitride (HfON), hafnium aluminum oxide (HfAlO), zirconium oxide (ZrO₂), tantalum oxide (Ta₂O₃), hafnium tantalum oxide (HfTaₓO_{y}), lanthanum oxide (LaO), lanthanum aluminum oxide (LaAlO), lanthanum hafnium oxide (LaHfO), and hafnium aluminum oxide (HfAlO).

The cell gate electrode 114 may be a single layer or a multi-layer including at least one of polysilicon, aluminum (Al), gold (Au), beryllium (Be), bismuth (Bi), cobalt (Co), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), zirconium (Zr), nitrides thereof, and silicides thereof.

The cell spacer 116 and the cell capping layer 118 may include oxide, nitride, or oxynitride, for example, silicon oxide (SiO₂), silicon oxynitride (SiON), or silicon nitride (SiN).

The peripheral transistors 120 may each include a gate insulating layer 122, a gate electrode 124, a spacer 126, and optionally a capping layer 128. The gate insulating layer 122 may include the same materials as the tunneling insulating layer 111 and/or the blocking insulating layer 113. The gate electrode 124 may include the same materials as the cell gate electrode 114. The spacer 126 and/or the capping layer 128 may include the same materials as the cell spacer 116 and/or the cell capping layer 118.

The cell transistors 110 each have a first height H1 and are spaced apart from each other by a first interval or distance W1. The peripheral transistors 120 each have a second height H2 and are spaced apart from each other by a second interval or distance W2. The second interval W2 between the peripheral transistors 120 is greater than the first interval W1 between the cell transistors 110. The second height H2 of one of the peripheral transistors 120 may be the same as or different from the first height H1 of one of the cell transistors 110. Also, the cell transistors 110 and the peripheral transistors 120 may be simultaneously formed during the same process or may be respectively formed in a separate process.

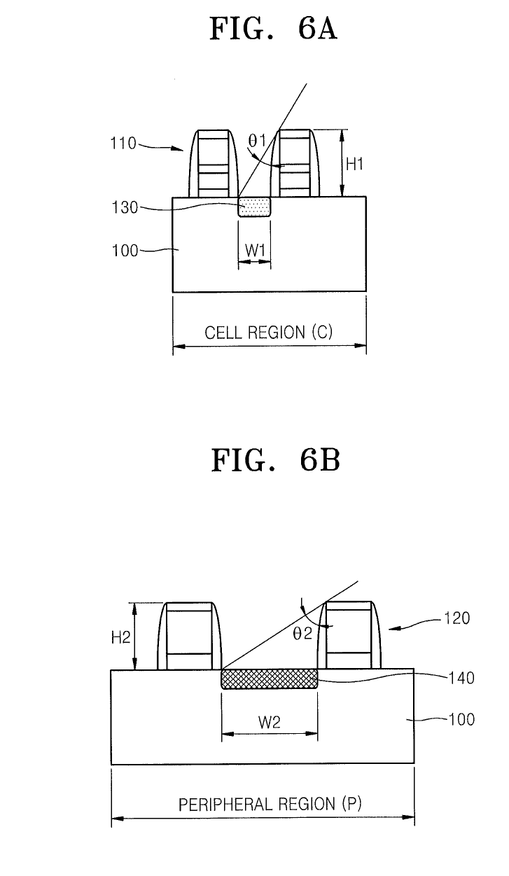

Referring to FIGS. 4 and 5B, a first ion implantation process is performed in operation S2. Accordingly, an active region disposed between the cell transistors 110, that is, a cell source/drain region 130, is implanted with the first ion. Simultaneously, an active region disposed between the peripheral transistors 120, that is, a peripheral source/drain region 140, is implanted with the first ion. In FIG. 5B, solid line arrows indicate an implantation direction of the first ion implanted into the cell source/drain region 130 and the peripheral source/drain region 140 and dashed line arrows indicate an implantation direction of the first ion blocked by the cell transistors 110 or the peripheral transistors 120. The solid line arrows and the dashed line arrows denote similar operations in the subsequent drawings of FIG. 5C and 5D. The first ion may include Group III elements or Group V elements, for example, arsenic (As). Also, as shown in FIG. 5B, the first ion may be vertically implanted substantially perpendicular or normal to the surface of the semiconductor layer 100; however, this is by way of example only, and the inventive concept is not limited thereto. For example, the first ion may be implanted at a first angle relative to a normal to the substrate (θ1 as shown in FIG. 6A). The definition and range of the first angle θ1 are described more fully with reference to FIG. 6A. Accordingly, when the first ion is implanted at a first angle, the first ion may be implanted in both directions that are symmetrical with a normal line to the surface of the semiconductor layer 100. As described herein, ion implantation at the same angle from two or more different directions may be referred to as “double-mode” ion implantation.

Referring to FIGS. 4, 5C, and 5D, a second ion implantation process is performed in operation S3. In the second ion implantation process, the peripheral source/drain regions 140 including portions of the peripheral region disposed between the peripheral transistors 120 are implanted with a second ion at a second angle relative to a normal to the substrate; however, due to the second angle of implantation (θ2 as shown in FIG. 6B), the cell source/drain regions 130 including portions of the cell region disposed between the cell transistors 110 are not implanted with the second ion. The definition and range of the second angle θ2 are described more fully with reference to FIG. 6B. The second ion may include Group III elements or Group V elements, for example, phosphorus (P). The second ion may be the same as or different from the first ion. For example, when the first ion is As, the second ion may be P. In general, the molecular weight of P is less than that of As so that the second ion may be easily diffused in the semiconductor layer 100; however, this is by way of example only, and the inventive concept is not limited thereto.

Referring to FIG. 5C, when the second ion is implanted in a first direction, a portion 142 of the peripheral source/drain region 140 may be implanted with the second ion, since the second ion implantation is partially blocked by the peripheral transistor 120. Also, the height H1 of the cell transistors 110 is sufficient to block implantation of the second ion into portions of the cell region between the cell transistors 110 when the second ion is implanted at the second angle θ2.

Referring to FIG. 5D, the second ion is implanted in a second direction different from the first direction. The first direction and the second direction may be symmetrical with each other with respect to the normal line to the surface of the semiconductor layer 100. That is, implantation of the second ion in the first direction as shown in FIG. 5C and implantation of the second ion in the second direction as shown in FIG. 5D may provide the double-mode implantation as described above. When the second ion is implanted in the second direction, the remaining portion of the peripheral source/drain region 140 may be implanted with the second ion. Accordingly, the portion of the peripheral source/drain region 140 that was not implanted with the second ion (in FIG. 5C) is implanted with the second ion, and thus, most and/or all of the peripheral source/drain region 140 is implanted with the second ion. Likewise, the height H1 of the cell transistors 110 is sufficient to block implantation of the second ion into portions of the cell region between the cell transistors 110.

FIG. 6A is a cross-sectional view illustrating a range of the first angle at which the first ions are implanted. FIG. 6B is a cross-sectional view illustrating a range of the second angle at which the second ions are implanted.

Referring to FIG. 6A, if the cell source/drain region 130 is to be implanted with the first ion, the first ion may not be blocked by the cell transistors 110. Accordingly, the cell source/drain region 130 may be implanted with the first ion at the first angle θ1 within a predetermined range. The maximum value θ1(max) of the first angle θ1 at which the cell source/drain region 130 may be implanted is represented by Equation 1.

θ1(max)=tan⁻¹(W1/H1) [Equation 1]

where H1 is the first height of each of the cell transistors 110 and W1 is the distance or interval between the cell transistors 110.

Accordingly, the cell source/drain region 130 of the cell transistors 110 and the peripheral source/drain region 140 of the peripheral transistors 120 are implanted with the first ion at the first angle θ1 within the range represented by Equation 2.

0≦θ1≦θ1(max) [Equation 2]

Referring to FIG. 6B, if the peripheral source/drain region 140 is to be implanted with the second ion, the second ion may not be blocked by the peripheral transistors 120. Accordingly, the peripheral source/drain region 140 may be implanted with the second ion at the second angle θ2 within a predetermined range. The maximum value θ2(max) of the second angle θ2 at which the peripheral source/drain region 140 is implanted is represented by Equation 3.

θ2(max)=tan⁻¹(W2/H2) [Equation 3]

where H2 is the second height of each of the peripheral transistors 120 and W2 is the interval or distance between the peripheral transistors 120.

As described above, during the second ion implantation process in operation S3, the second ion is not implanted into the cell source/drain region 130. Accordingly, the second angle θ2 may be greater than the maximum value θ1(max) of the first angle θ1, which is the maximum angle at which the cell source/drain region 130 is implanted. Thus, the peripheral source/drain region 140 of the peripheral transistors 120 is implanted with the first ion at the second angle θ2 within the range represented by Equation 4.

θ1(max)<θ2≦θ2(max) [Equation 4]

As described above, the cell source/drain region 130 is implanted with the first ion and the peripheral source/drain region 140 is implanted with the first and second ions. Also, the ionic concentration of the peripheral source/drain region 140 may be higher than that of the cell source/drain region 130. For example, the ionic concentration of the peripheral source/drain region 140 may be higher that that of the cell source/drain region 130 by about 1.5 to about 5 times. After the ion implantation processes are completed, the cell source/drain region 130 may include As ions and the peripheral source/drain region 140 may include As ions and P ions in some embodiments.

In some embodiments of the inventive concept, the cell source/drain region 130 and the peripheral source/drain region 140 may be formed to each have different doping concentrations so that a short channel effect of the cell transistors 110 may be reduced and the peripheral transistors 120 may have ionic concentrations which may maintain a breakdown voltage. Also, a separate photolithography process is not required, and thus, the ion implantation process may be simplified.

According to further embodiments, the first ion implantation process S2, by which the cell source/drain region 130 of the cell transistors 110 is implanted with the first ion, may not be performed and instead the second ion implantation process S3, by which the peripheral source/drain region 140 of the peripheral transistors 120 is implanted with the second ion, may be only performed. In this case, the ionic concentration of the peripheral source/drain region 140 may be higher than that of the cell source/drain region 130. After the second ion implantation process S3 is completed, the peripheral source/drain region 140 may include P ion.

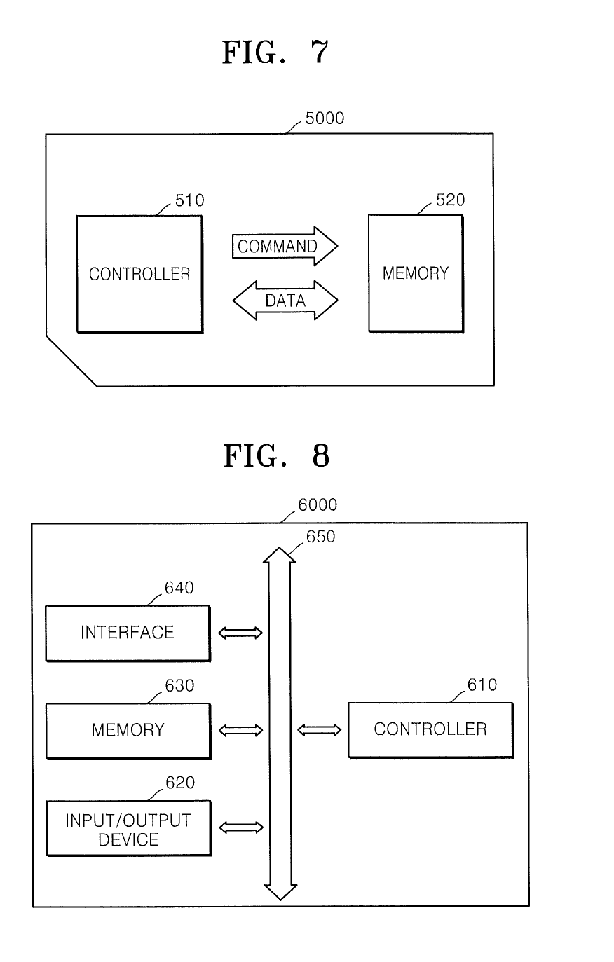

FIG. 7 illustrates a memory card 5000 according to some embodiments of the inventive concept.

Referring to FIG. 7, a controller 510 and a memory 520 are disposed in the memory card 5000 to exchange electric signals with each other. For example, when the controller 510 outputs a command to the memory 520, the memory 520 may output data to the controller 510. The memory 520 may include a non-volatile memory device according to any of the embodiments of the inventive concept. The non-volatile memory devices according to the embodiments of the inventive concept. The non-volatile memory devices according to the various embodiments of the inventive concept may be disposed as “NAND” or “NOR” architecture memory arrays (not shown) in correspondence to logic gate design that is well-known in the art. The memory arrays disposed in a plurality of rows and columns may have one or more memory array banks (not shown). The memory 520 may include a memory array (not shown) or a memory array bank (not shown). In addition, the memory card 5000 may further include a conventional row decoder (not shown), a column decoder (not shown), input/output (I/O) buffers (now shown), and/or a control resistor (not shown) in order to drive the memory array bank (not shown). The memory card 5000 may be used in memory devices as a memory card, for example, a memory stick card, a smart media (SM) card, a secure digital (SD) card, a mini SD card, or a multi media card (MMC).

FIG. 8 illustrates a system 6000 according to an embodiment of the inventive concept.

Referring to FIG. 8, the system 6000 may include a controller 610, an input/output device 620, a memory 630, and an interface 640. The system 6000 may be a mobile system or a system that transmits or receives data. The mobile system may be, for example, a personal digital assistant (PDA), a portable computer, a web tablet, a wireless phone, a mobile phone, a digital audio player, or a memory card. The controller 610 may execute a software program and control the system 6000. The controller 610 may be, for example, a microprocessor, a digital signal processor, a microcontroller, or the like. The input/output device 630 can be used to input or output data to or from the system 6000. The input/output device 620 may be used to input or output data of the system 6000. The system 6000 may be connected to an external apparatus, for example, a personal computer or a network, by using the input/output device 620 to exchange data with the external apparatus. The input/output device 620 may be, for example, a keypad, a keyboard, and/or a display device. The memory 630 may store code and/or data for operating the controller 610 and/or may store data processed by the controller 610. The memory 630 may include a non-volatile memory device according to any of the embodiments of the present invention. The interface 640 may be a data transmission path between the system 6000 and an external apparatus. The controller 610, the input/output device 620, the memory 630, and the interface 640 may communicate with one another via a bus 650. For example, the system 6000 may be used for a mobile phone, an MP3 player, a navigation system, a portable multimedia player (PMP), a solid-state disk (SSD), or a household appliance.

While embodiments of the inventive concept have been particularly shown and described with reference to exemplary embodiments thereof, it will be understood that various changes in form and details may be made therein without departing from the spirit and scope of the following claims.

That which is claimed:

1. A method of fabricating a non-volatile memory device, the method comprising:
forming a plurality of memory cell transistor gates on a cell region of a substrate surface and a plurality of peripheral transistor gates on a peripheral region of the substrate surface, wherein a distance between adjacent ones of the peripheral transistor gates is greater than a distance between adjacent ones of the memory cell transistor gates; and
performing an ion implantation process at an implantation angle that is selected based on a height of the memory cell transistor gates and the distance between the adjacent ones thereof to implant ions into portions of the peripheral region between the peripheral transistor gates without implanting the ions into portions of the cell region between the memory cell transistor gates.

2. The method of claim 1, wherein the height of the memory cell transistor gates is sufficient to block implantation of the ions into the portions of the cell region therebetween in response to performing the ion implantation process at the implantation angle.

3. The method of claim 2, wherein the implantation angle is measured relative to a normal to the substrate surface, and wherein the implantation angle is greater than an inverse tangent of the distance between the adjacent ones of the memory cell transistor gates divided by the height of the memory cell transistor gates.

4. The method of claim 3, wherein the implantation angle is not greater than an inverse tangent of the distance between adjacent ones of the peripheral transistor gates divided by a height of the peripheral transistor gates.

5. The method of claim 4, wherein implantation angle comprises a second implantation angle, wherein the ion implantation process comprises a second ion implantation process to implant second ions at the second implantation angle, and further comprising:
performing a first ion implantation process at a first implantation angle different from the second implantation angle to implant first ions into the portions of the cell region between the memory cell transistor gates and into the portions of the peripheral region between the peripheral transistor gates.

6. The method of claim 5, wherein the first implantation angle is measured relative to the normal to the substrate surface, and wherein the second implantation angle is greater than the first implantation angle.

7. The method of claim 6, wherein the first implantation angle is not greater than the inverse tangent of the distance between the adjacent ones of the memory cell transistor gates divided by the height of the memory cell transistor gates.

8. The method of claim 5, wherein the first ions comprise ions of a different material than the second ions.

9. The method of claim 8, wherein the first ions have a greater molecular weight than the second ions.

10. The method of claim 1, wherein performing the ion implantation process comprises performing the ion implantation process at the implantation angle from at least two different directions.

11. A method of manufacturing a non-volatile memory device, the method comprising:
preparing a semiconductor layer including a cell region and a peripheral region;
forming a plurality of cell transistors in the cell region and a plurality of peripheral transistors in the peripheral region;
implanting first ions at a first angle θ1 into cell source/drain regions of the cell transistors and peripheral source/drain regions of the peripheral transistors; and
implanting second ions different from the first ions at a second angle θ2 into the peripheral source/drain regions and not into the cell source/drain regions.

12. The method of claim 11, wherein the first angle θ1 is in a range of 0≦θ1≦θ1(max),
wherein, θ1(max)=tan⁻¹(W1/H1), H1 is a first height of each of the cell transistors, and W1 is an interval between the cell transistors.

13. The method of claim 11, wherein the second angle θ2 is in a range of θ1(max)<θ2≦θ2(max),
wherein θ2(max)=tan⁻¹(W2/H2), H2 is a second height of each of the peripheral transistors, and W2 is an interval between the peripheral transistors.

14. The method of claim 11, wherein at least one of the implanting of the first ions and the second ions is performed in a double-mode at a same angle from at least two different directions.

15. The method of claim 11, wherein the first ions and the second ions comprise Group III elements or Group V elements, respectively.

16. The method of claim 11, wherein the first ions and the second ions are different from each other.

17. The method of claim 11, wherein the molecular weights of the first ions are greater than those of the second ions.

18. The method of claim 11, wherein the first ions comprise arsenic (As) and the second ions comprise phosphorus (P).

19. The method of claim 11, wherein the cell transistors each comprise a tunneling insulating layer, a charge storage layer, a blocking insulating layer, and a cell gate electrode that are stacked sequentially on the semiconductor layer.

20. A method of manufacturing a non-volatile memory device, the method comprising:
preparing a semiconductor layer including a cell region and a peripheral region;
forming a plurality of cell transistors each comprising a charge storage layer in the cell region and a plurality of peripheral transistors in the peripheral region; and
implanting second ions at a second angle θ2 into peripheral source/drain regions of the peripheral transistors and not into cell source/drain regions of the cell transistors, wherein the second angle θ2 is in a range of θ1(max)<θ2≦θ2(max), wherein θ1(max)=tan⁻¹(W1/H1), θ2(max)=tan⁻¹(W2/H2), H2 is a second height of each of the peripheral transistors, W2 is an interval between the peripheral transistors, H1 is a first height of each of the cell transistors, and W1 is an interval between the cell transistors.
